(19) United States
(12) Patent Application Publication
(10) Pub. No.: US 2024/0112889 A1
(43) Pub. Date: Apr. 4, 2024

(54) LARGE DIAMETER POROUS PLUG FOR ARGON DELIVERY

(71) Applicant: Applied Materials, Inc., Santa Clara, CA (US)

(72) Inventors: Tony Jefferson GNANAPRAKASA, Mountain View, CA (US); Alvaro GARCIA, Mountain View, CA (US); Martin Perez GUZMAN, Santa Clara, CA (US); Stephen Donald PROUTY, San Jose, CA (US)

(21) Appl. No.: 18/372,811

(22) Filed: Sep. 26, 2023

Related U.S. Application Data
(60) Provisional application No. 63/412,271, filed on Sep. 30, 2022.

(51) Int. Cl. H01J 37/32; H01L 21/67; H01L 21/683

(52) U.S. Cl. CPC H01J 37/3244; H01J 37/32715; H01L 21/67069; H01L 21/6833

(57) ABSTRACT

The disclosure relates to a substrate support assembly for reducing the evacuation time when using argon gas. In one embodiment, a substrate support assembly includes a porous plug within the substrate support assembly. The porous plug includes a first cylindrical section with a first volume and axial length, a second cylindrical section with a second volume and axial length. The first cylindrical section has a larger volume than the second cylindrical section. The first cylindrical section and second cylindrical section have a volume ratio between about 2 and about 12. The first cylindrical section axial length and second cylindrical section axial length have a length ratio between about 2 and about 10.

### CROSS-REFERENCE TO RELATED APPLICATIONS

This application claims benefit of U.S. Provisional Patent Application No. 63/412,271, filed on Sep. 30, 2022, the entirety of which is herein incorporated by reference.

### BACKGROUND

### Field

Embodiments of the present invention generally relate to semiconductor processing and manufacturing. In semiconductor processing, a plasma process is often performed in vacuum by evacuating gas from a processing chamber. In such a process, a substrate is placed on an electrostatic chuck (ESC) that is arranged on a stage of a processing chamber. The electrostatic chuck includes a conductive sheet-type chucking electrode that is arranged between dielectric members (e.g., dielectric layers).

### Description of the Related Art

Helium is a commonly used backside gas in semiconductor processing. However, helium is expensive and increases the cost of processing substrates when using such a gas. Additionally, when an electrostatic chuck's chucking voltage is increased, the resultant force causes additional vacuum leaks when using helium due to its small atomic size. Thus, a process chamber may experience pressure and vacuum instability when utilizing as a backside gas.

Therefore, there is a need for apparatus and methods that improve backside gas processes during semiconductor processing operations.

### SUMMARY

In one embodiment, a substrate support assembly includes a porous plug within the substrate support assembly. The porous plug includes a first cylindrical section with a first volume and axial length, a second cylindrical section with a second volume and axial length. The first cylindrical section has a larger volume than the second cylindrical section. The first cylindrical section and second cylindrical section have a volume ratio between about 2 and about 12. The first cylindrical section axial length and second cylindrical section axial length have a length ratio between about 2 and about 10.

In another embodiment, a processing chamber, includes one or more walls enclosing a process volume and a substrate support assembly disposed in the process volume. The substrate support assembly includes an electrostatic chuck disposed above an insulator plate and a porous plug disposed within the insulator plate. The porous plug includes a material having a porosity, a first cylindrical section having a first volume, a first diameter, and a first axial length and a second cylindrical section having a second volume less than the first volume, a second diameter less than the first diameter, and second axial length less than the first axial length.

In another embodiment, a porous plug includes a cross-linked polystyrene material having a uniform porosity, a first cylindrical section having a first volume, a first diameter, and a first axial length, and a second cylindrical section with a second volume less than the first volume, a second diameter less than the first diameter and second axial length less than the first axial length. A volume ratio between the volume of the first cylindrical section and the volume of the second cylindrical section is between about 2 and about 12. A first cylindrical section is disposed between the second cylindrical section and a process volume. A length ratio between the first axial length and the second axial length is between about 2 and about 10.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of its scope, and may admit to other equally effective embodiments.

FIG. 1 illustrates a cross-sectional schematic view of a plasma processing chamber, according to an embodiment in the disclosure.

FIG. 2 illustrates a cross-sectional schematic of a substrate support assembly, according to an embodiment in the disclosure.

FIG. 3 illustrates a cross-sectional schematic of a porous plug within a chamber, according to an embodiment in the disclosure.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Embodiments described herein provide a substrate support assembly with a porous plug which enables operation of an electrostatic chuck (ESC) with a backside gas that is more economical than helium so that a substrate disposed thereon is maintained at a temperature less than −20° C. during substrate processing while other surfaces of a processing chamber are maintained at a different temperature.

Although the substrate support assembly is described below in an etch processing chamber, the substrate support assembly may be utilized in other types of plasma processing chambers, such as physical vapor deposition chambers, chemical vapor deposition chambers, ion implantation chambers, among others, and other systems where processing necessitates a substrate maintained at temperatures less than −20° C. The substrate support assembly disclosed herein may also be utilized at temperatures less than −20° C.

It has been found that use of argon has advantages in a number of substrate processes including, reduced vacuum leakage when compared to helium. Also, when argon is utilized as a backside gas, the backside gas rate into the processing region is controllable at a substantially constant rate. In contrast, helium leakage into the processing region is observed at a higher rate when vacuum pressures are increased which results in potentially reduced gas rate control. Because argon is a larger molecule than helium, argon gas delivery time is greater than helium when using the same backside gas delivery apparatus.

Embodiments described herein provide for a plug design which enables argon to have similar backside gas evacuation times to helium while also retaining the benefits of less leakage in the isolation vacuum and less backside gas leakage at higher pressure.

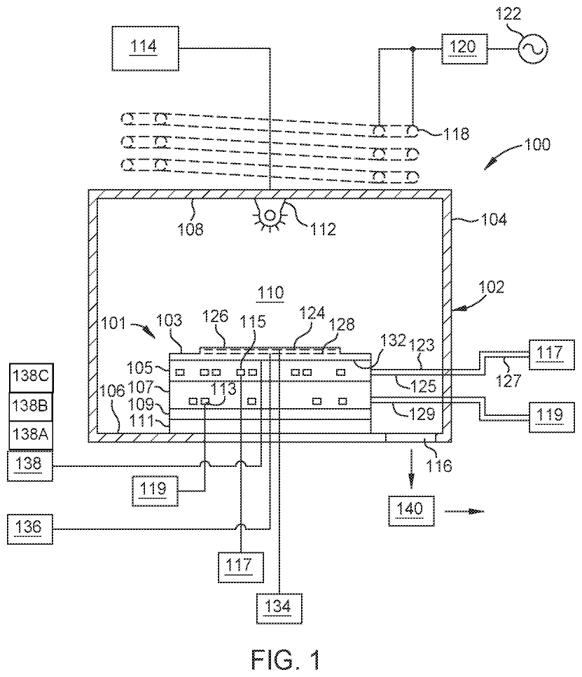

FIG. 1 illustrates a cross-sectional schematic view of an exemplary plasma processing chamber 100, shown configured as an etch chamber, having a substrate support assembly 101. The substrate support assembly 101 may be utilized in other types of plasma processing chambers, for example plasma treatment chambers, annealing chambers, physical vapor deposition chambers, chemical vapor deposition chambers, and ion implantation chambers, among others, as well as other systems where the ability to uniformly maintain a surface or work piece, such as a substrate 124, at temperatures less than −20° C. is desirable.

The plasma processing chamber 100 includes a chamber body 102 having sidewalls 104, a bottom 106 and a lid 108 that enclose a processing volume 110. An injection apparatus 112 is coupled to the sidewalls 104 and/or lid 108 of the chamber body 102. A gas panel 114 is coupled to the injection apparatus 112 to allow process gases to be provided into the processing volume 110. The injection apparatus 112 may be one or more nozzle or inlet ports, or alternatively a showerhead. Process gases, along with any processing by-products, are removed from the processing volume 110 through an exhaust port 116 formed in the sidewalls 104 or bottom 106 of the chamber body 102. The exhaust port 116 is coupled to a pumping system 140, which includes throttle valves and pumps utilized to control the vacuum levels within the processing volume 110.

The process gases may be energized to form a plasma within the processing volume 110. The process gases may be energized by capacitively or inductively coupling radio frequency (RF) power to the process gases. In the embodiment, which can be combined with other embodiments described herein, depicted in FIG. 1, a plurality of coils 118 are disposed above the lid 108 of the plasma processing chamber 100 and coupled through a matching circuit 120 to an RF power source 122.

The substrate support assembly 101 is disposed in the processing volume 110 below the injection apparatus 112. The substrate support assembly 101 includes an electrostatic chuck (ESC) 103 and an ESC base 105. The ESC base 105 is coupled to the ESC 103 and a facility plate 107. The facility plate 107 supported by a ground plate 111 is configured to facilitate electrical, cooling, heating, and gas connections with the substrate support assembly 101. The ground plate 111 is supported by the bottom 106 of the processing chamber. An insulator plate 109 insulates the facility plate 107 from the ground plate 111.

The ESC base 105 includes a base channel 115 coupled to a cryogenic chiller 117. The cryogenic chiller 117 is in fluid communication with the base channel 115 via a base inlet conduit 123 connected to an inlet of the base channel 115 and via a base outlet conduit 125 connected to an outlet of the base channel 127 such that the ESC base 105 is maintained at temperatures less than −20° C. The cryogenic chiller 117 is coupled to an interface box to control a flow rate of a base fluid. The base fluid may include a material that can maintain a temperature less than −50° C. The cryogenic chiller 117 provides the base fluid, which is circulated through the base channel 115 of the ESC base 105. The base fluid flowing through the base channel 115 enables the ESC base 105 to be maintained at temperatures less than −20° C., which assists in controlling the lateral temperature profile of the ESC 103 so that a substrate 124 disposed on the ESC 103 is uniformly maintained at temperatures less than −20° C. ° C. In one embodiment, which can be combined in other embodiments described herein, the cryogenic chiller 117 is a single-stage chiller operable to maintain the base fluid at temperature less than about −50° C. In another embodiment, which can be combined in other embodiments described herein, the cryogenic chiller 117 is a chiller that utilizes refrigerant internal to the chiller such the base fluid is maintained at temperatures less than −50° C.

The facility plate 107 includes a facility channel 113 coupled to a chiller 119. The chiller 119 is in fluid communication with the facility plate 107 via a facility inlet conduit 129 such that the facility plate 107 is maintained a predetermined ambient temperature. The cryogenic chiller 117 is coupled to an interface box to control a flow rate of the facility fluid. The facility fluid may include a material that can maintain an ambient temperature between about −10° C. to about 60° C. The chiller 119 provides the facility fluid, which is circulated through the facility plate 107. The facility fluid enables the facility plate 107 to be maintained at the predetermined ambient temperature, which assists in maintaining the insulator plate 109 at the predetermined ambient temperature.

The ESC 103 has a support surface 130 and a bottom surface 132 opposite the support surface 130. In one embodiment, which can be combined with other embodiments described herein, the ESC 103 is fabricated from a ceramic material, such as alumina (Al₂O₃), aluminum nitride (AlN) or other suitable material. Alternately, the ESC 103 may be fabricated from a polymer, such as polyimide, polyetheretherketone, polyaryletherketone and the like.

The ESC 103 includes a chucking electrode 126 disposed therein. The chucking electrode 126 may be configured as a mono polar or bipolar electrode, or other suitable arrangement. The chucking electrode 126 is coupled through an RF filter and the facility plate 107 to a chucking power source 134, which provides a DC power to electrostatically secure the substrate 124 to the support surface 130 of the ESC 103. The RF filter prevents RF power utilized to form a plasma (not shown) within the plasma processing chamber 100 from damaging electrical equipment or presenting an electrical hazard outside the chamber.

The ESC 103 includes one or more resistive heaters 128 embedded therein. The resistive heaters 128 are utilized to elevate the temperature of the ESC 103 to the temperature suitable for processing a substrate 124 disposed on the support surface 130. The resistive heaters 128 are coupled through the facility plate 107 and an RF filter to a heater power source 136. The RF filter prevents RF power utilized to form a plasma (not shown) within the plasma processing chamber 100 from damaging electrical equipment or presenting an electrical hazard outside the chamber. The heater power source 136 may provide 500 watts or more power to the resistive heaters 128. The heater power source 136 includes a controller 138 utilized to control the operation of the heater power source 136, which is generally set to heat the substrate 124 when needed in order to maintain the substrate temperature at a desired temperature under −20° C. Stated differently, heat from the resistive heaters 128 and cooling from the base fluid circulating through the ESC base 105 are balanced to maintain the substrate 124 at a desired temperature under −20° C. For example, the resistive heaters 128 and the base fluid circulating through the ESC base 105 maintain the substrate 124 at a temperature suitable for processing that is less than about −20° C., such as between about −20° C. to about −150° C.

The resistive heaters 128 include a plurality of laterally separated heating zones, wherein the controller 138 enables at least one zone of the resistive heaters 128 to be preferentially heated relative to the resistive heaters 128 located in one or more of the other zones. For example, the resistive heaters 128 may be arranged concentrically in a plurality of separated heating zones. The separated heating zones of the resistive heaters 128 assist controlling the lateral edge to center temperature uniformity of the substrate 124. The substrate support assembly 101 may also include one or more probes (not shown) disposed therein. The ESC 103 is coupled a controller 138. The probes disposed in the ESC base 105 are communicatively coupled to the controller 138 and may be utilized together to calibrate of the temperature of the substrate based on the temperature of the ESC base 105. The controller 138 is coupled to the heater power source 136 so that each zone of the resistive heaters 128 is independently heated for the lateral temperature profile of the ESC 103 to be substantially uniform based on temperature measurements so that a substrate 124 disposed on the ESC 103 is uniformly maintained at temperatures less than −20° C.

The controller 138 includes a programmable central processing unit (CPU) 138A which is operable with a memory 138B (e.g., non-volatile memory) and support circuits 138C. The support circuits 138C are conventionally coupled to the CPU 138A and comprise cache, clock circuits, input/output subsystems, power supplies, and the like, and combinations thereof coupled to the various components of the chamber 100, to facilitate control thereof. The CPU 138A is one of any form of general purpose computer processor used in an industrial setting, such as a programmable logic controller (PLC), for controlling various components and sub-processors of the processing system. The memory 138B, coupled to the CPU 138A, is non-transitory and is typically one or more of readily available memories such as random access memory (RAM), read only memory (ROM), floppy disk drive, hard disk, or any other form of digital storage, local or remote.

Typically, the memory 138B is in the form of a non-transitory computer-readable storage media containing instructions (e.g., non-volatile memory), which when executed by the CPU, facilitates the operation of the chamber 100. The instructions in the memory are in the form of a program product such as a program that implements the methods of the present disclosure. The program code may conform to any one of a number of different programming languages. In one example, the disclosure may be implemented as a program product stored on computer-readable storage media for use with a computer system. The program(s) of the program product define functions of the embodiments (including the methods described herein).

Illustrative non-transitory computer-readable storage media include, but are not limited to: (i) non-writable storage media (e.g., read-only memory devices within a computer such as CD-ROM disks readable by a CD-ROM drive, flash memory, ROM chips or any type of solid-state non-volatile semiconductor memory devices, e.g., solid state drives (SSD)) on which information may be permanently stored; and (ii) writable storage media (e.g., floppy disks within a diskette drive or hard-disk drive or any type of solid-state random-access semiconductor memory) on which alterable information is stored. Such computer-readable storage media, when carrying computer-readable instructions that direct the functions of the methods described herein, are embodiments of the present disclosure. In some embodiments, the methods set forth herein, or portions thereof, are performed by one or more application specific integrated circuits (ASICs), field-programmable gate arrays (FPGAs), or other types of hardware implementations. In some other embodiments, the substrate processing and/or handling methods set forth herein are performed by a combination of software routines, ASIC(s), FPGAs and, or, other types of hardware implementations. One or more system controllers 138 may be used with one or any combination of the various modular polishing systems described herein and/or with the individual polishing modules thereof.

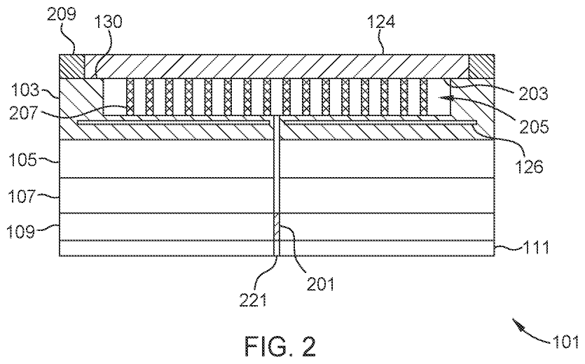

FIG. 2 illustrates the cross-section of the substrate support assembly 101. The substrate support assembly 101 includes the ESC 103, ESC base 105, facility plate 107, insulator plate 109, ground plate 111, and an edge ring 209.

The chucking electrodes 126 within the ESC 103 provide chucking force when voltage and current pass through the substrate 124 and ESC 103. The voltage and current pass through when a substrate lower surface 203 contacts the support surface 130.

The support surface 130 includes the top surface of a plurality of posts 207 disposed within a backside gas cavity 205 in the ESC 103. The cavity 205 may be sealed or partially sealed from the processing volume 110 (FIG. 1) by the support surface 130 and substrate lower surface 203 when chucked via the chucking electrode 126.

The backside gas cavity 205 may be supplied and have gas exhausted through a backside gas conduit 221. When the cavity 205 is filled with a backside gas it further aids thermal energy transfer between the ESC 103 and the substrate 124. The backside gas supplied by the backside gas conduit 221 passes through a plug 201. In some embodiments the plug 201 is disposed in the insulator plate 109. The plug 201 is described in more detail below.

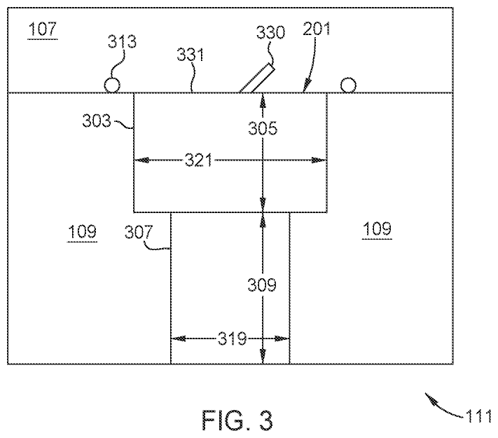

FIG. 3 illustrates the plug 201 for delivery of a backside gas to a substrate disposed on the ESC 103 of the substrate support assembly 101. The plug 201 is configured to reduce the backside gas supply and evacuation time when using a gas with an atomic mass larger than that of helium, for example, when utilizing argon or another inert gas. The plug 201 exhibits fluid flow rate which is dependent upon a porosity of the material utilized to fabricate the plug 201. In some embodiments, the plug 201 is made of cross-linked polystyrene material with uniform porosity. In some embodiments, the plug 201 material has a dielectric constant between about 2 and about 3, for example about 2.5. In one embodiment, the porosity of the plug 201 is a function of the material grit size utilized to fabricate the plug 201. In one embodiment, the grit size of the plug is between about 50 μm and about 200 μm, such as between about 100 μm and about 150 μm, for example, between about 115 μm and about 130 μm. The grit size selected may influence the porosity of the plug 201. In one embodiment, a singular grit size is utilized to fabricate the plug 201. In this embodiment, the porosity of the plug 201 is substantially uniform. In another embodiment, a plurality of grit sizes may be utilized to fabricate the plug 201. In this embodiment, the porosity of the plug 201 is uniform or non-uniform, depending upon the distribution of the different grit size materials within the plug 201.

The plug 201 has a top section 303 and a bottom section 307. The top section 303 has a top diameter 321, a top axial length 305, a top cross-sectional area, and a top volume. The bottom section 307 has a bottom diameter 319, a bottom axial length 309, a bottom cross-sectional area, and a bottom volume.

The top diameter 321 is between about 0.45 inches and about 0.55 inches. The top axial length 305 is between about 1 inches and about 1.3 inches. The top cross-sectional area is between about 0.15 and about 0.2 square inches. The top volume is between about 0.2 and about 0.3 cubic inches.

The bottom diameter 319 is between about 0.35 inches and about 0.45 inches. The bottom axial length 309 is between about 0.1 inches and about 0.3 inches. The bottom cross-sectional area is between about 0.1 and about 0.2 square inches. The bottom volume is between about 0.02 and about 0.04 cubic inches.

The top diameter 321 is greater than the bottom diameter 319. The top axial length 305 is greater than the bottom axial length 309. The cross-sectional area of the bottom section 307 is smaller than the cross-sectional area of top section 303. The top section 303 and the bottom section 307 have a volume ratio of between about 2 and about 12, such as between about 4 and about 10, for example, between about 7 and about 7.4. The top axial length 305 and the bottom axial length 309 have a ratio of between about 2 and about 10, such as between about 4 and about 6, for example, between about 5.05 and about 5.07. In this embodiment, the plug 201 enables a greater amount of backside (e.g. argon) to flow through the plug 201 which results in increased argon flow rates, and ultimately, increased throughput.

Alternatively, the porosity, diameters, volume ratios, and axial lengths of the plug 201 may be altered to achieve improved flow rates of backside gas.

The plug 201 is disposed within an insulator plate 109 having a top plug section face 331 opposite the bottom section 307. The top section 303 is disposed adjacent to or in contact with a bottom of the facility plate 107. The upper surface of the insulator plate 109, the lower surface of the facility plate 107, and the top plug section face 331 are disposed within substantially the same plane. The plug 201 is at a connection to the backside gas conduit 330. The backside gas conduit can be a single central flow line, or can be a network of conduits through the facility plate 107, ESC base 105, and ESC 103 to provide and exhaust back side gas to the substrate 124.

The plug 201 is configured to allow the passage of gas, but prevent arcing between the process volume 110 and the ground plate 111.

Surrounding the top plug section face 331 is an elastomeric seal 313. The seal 313 is disposed between the insulator plate 109 and the facility plate 107. Alternatively, the seal 313 is recessed in the facility plate 107. The seal 313 enables sealing of gases, at both high and low temperatures, and is capable of sealing against atmospheric and sub-atmospheric pressures. In another embodiment, the plug 201 is disposed within or adjacent to the ESC base 105 and the plug is configured to deliver a gas therethrough to a backside of the substrate 124 disposed on the ESC 103.

While the leak rate of helium is typically greater than that of argon, utilizing the plug 201 to deliver argon to a backside of the substrate can significantly increase the leak rate of argon therethrough and enable argon gas delivery rates which are comparable or even greater than that of helium. As such, the time utilized for argon backside gas delivery can be reduced by utilizing the plug 201 and throughput gains may be realized.

The plug described herein enables helium to be replaced with argon as a backside gas. Helium is a conventional backside gas due to its small molecular size that enables high flow through other conventional plugs. Helium is expensive thereby adding costs to semiconductor manufacture. Argon is not compatible with conventional backside gas plugs due to its larger molecular size.

While the foregoing is directed to embodiments of the present disclosure, other and further embodiments of the disclosure may be devised without departing from the basic scope thereof, and the scope thereof is determined by the claims that follow.

What is claimed is:

1. A substrate support assembly, comprising:
an electrostatic chuck;
an insulator plate; and
a porous plug disposed within the insulator plate, wherein the porous plug comprises:
a first cylindrical section having a first volume and a first axial length; and
a second cylindrical section having a second volume and a second axial length, wherein:
the first volume is greater than the second volume; and
the first axial length is greater than the second axial length.

2. The substrate support assembly of claim 1, wherein the porous plug further comprises a porosity as a function of a grit size, the grit size being between about 50 μm and about 200 μm.

3. The substrate support assembly of claim 1, wherein the first axial length is between 0.9″ and 1.1″.

4. The substrate support assembly of claim 1, wherein the first cylindrical section further comprises a first diameter and the second cylindrical section further comprises a second diameter less than the first diameter.

5. The substrate support assembly of claim 4, wherein a ratio between the first diameter and second diameter is between about 1 and about 1.4.

6. The substrate support assembly of claim 1, wherein the first cylindrical section further comprises a first cross-sectional area and the second cylindrical section further comprises a second cross-sectional area less than the first cross-sectional area.

7. The substrate support assembly of claim 6, wherein a ratio between the first cross-section and second cross-section is between about 1 and about 2.

8. The substrate support assembly of claim 1, wherein a length ratio between the first axial length and the second axial length is between about 2 and about 10.

9. The substrate support assembly of claim 1, wherein a volume ratio between the first volume and the second volume is between about 2 and about 12.

10. A processing chamber, comprising:
one or more walls enclosing a process volume; and
a substrate support assembly disposed in the process volume, the substrate support assembly comprising:
an electrostatic chuck disposed above an insulator plate; and
a porous plug disposed within the insulator plate, wherein the porous plug comprises:
a material having a porosity;
a first cylindrical section having a first volume, a first diameter, and a first axial length; and
a second cylindrical section having a second volume less than the first volume, a second diameter less than the first diameter, and second axial length less than the first axial length.

11. The processing chamber of claim 10, wherein the porosity is a function of a grit size, the grit size being between about 50 μm and about 200 μm.

12. The processing chamber of claim 11, wherein the porous plug is configured to allow flow of an inert gas.

13. The processing chamber of claim 12, wherein the inert gas is argon below about −40° C.

14. The processing chamber of claim 10, wherein, the substrate support assembly further comprises a facility plate disposed between the process volume and an insulator plate, the porous plug being disposed within the insulator plate.

15. The processing chamber of claim 10, wherein the material is a cross-linked polystyrene.

16. The processing chamber of claim 10, wherein the material has a dielectric constant between about 2 and about 3.

17. The processing chamber of claim 10, wherein:
a volume ratio between the volume of the first cylindrical section and the volume of the second cylindrical section is between about 2 and about 12;
the first cylindrical section is disposed between the second cylindrical section and the process volume; and
a length ratio between the first axial length and the second axial length is between about 2 and about 10.

18. A porous plug comprising:
a cross-linked polystyrene material having a uniform porosity;
a first cylindrical section having a first volume, a first diameter, and a first axial length; and
a second cylindrical section with a second volume less than the first volume, a second diameter less than the first diameter and second axial length less than the first axial length, wherein:
a volume ratio between the volume of the first cylindrical section and the volume of the second cylindrical section is between about 2 and about 12;
the first cylindrical section is disposed between the second cylindrical section and a process volume; and
a length ratio between the first axial length and the second axial length is between about 2 and about 10.

19. The porous plug of claim 18, wherein a ratio between the first diameter and second diameter is between about 1 and about 1.4.

20. The porous plug of claim 18, wherein the porosity is a function of a grit size, the grit size being between about 50 μm and about 200 μm.
